(19) United States
(12) Patent Application Publication
(10) Pub. No.: US 2010/0133092 A1
(43) Pub. Date: Jun. 3, 2010

(54) SPUTTERING METHOD AND SPUTTERING APPARATUS

(75) Inventors: Kimiko Mashimo, Tokyo (JP); Naomu Kitano, Tokyo (JP); Koji Tsunekawa, Tokyo (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/684,513

(22) Filed: Jan. 8, 2010

Related U.S. Application Data
(63) Continuation of application No. PCT/JP2007/067484, filed on Sep. 7, 2007.

(51) Int. Cl. C23C 14/36

(52) U.S. Cl. 204/192.21; 204/192.22

(57) ABSTRACT

A sputtering method and a sputtering apparatus are provided in which a target is disposed being inclined relative to a substrate placed on a substrate-placing table so that the condition of d≧D is satisfied, (d is the diameter of the substrate, and D is the diameter of the target), and the total number of rotations R of the substrate-placing table from the beginning of film-deposition on the substrate to the completion thereof becomes ten or more. Also the sputtering method and the sputtering apparatus are provided in which the rotational speed V of the substrate-placing table is controlled so that the total number of rotations R thereof satisfies the formula of

0.95×S−0.025≦R≦1.05×S+0.025

at R≦10, (R is the total number of rotations of the substrate-placing table from the beginning of film-deposition on the substrate to the completion thereof, and S is the value of the number of total rotations R rounded off to integer).

### CROSS-REFERENCES TO RELATED APPLICATIONS

This application is a continuation application of International Application No. PCT/JP2007/067484, filed on Sep. 7, 2007, the entire contents of which are incorporated by reference herein.

### BACKGROUND OF THE INVENTION

1. Field of the Invention

The present invention relates to a manufacturing method and a manufacturing apparatus to deposit an insulation film and a metal film, in the process of manufacturing a semiconductor device, to achieve high production yield of semiconductor elements and magnetoresistive elements at both intraplane and interplane of substrate through the deposition of the film having very thin and uniform thickness, and also relates to a semiconductor device. Specifically the present invention relates to a manufacturing method and a manufacturing apparatus for thinning a high-dielectric-constant film and for improving the performance of interface between the high-dielectric-constant film and a metal electrode material film, in metal-oxide-semiconductor field-effect transistor (MOSFET), and to a semiconductor device. Alternatively, the present invention relates to a manufacturing method and a manufacturing apparatus for depositing a magnetic tunnel junction (MTJ) used in a magnetic reproducing head of a magnetic disk drive unit, a memory element of magnetic random access memory (MRAM), and a magnetic sensor.

2. Related Background Art

Significant reduction in the size (represented by the gate size) of MOSFET devices is enhanced in recent years along with the increased integration and performance of semiconductor devices, and thus the gate insulation films are required to be as thin as 1.2 nm or smaller equivalent oxide thickness (EOT) with uniformity in the thickness. Regarding the gate insulation film using conventional silicon thermally oxidized film, however, since thinning of the film increases leak current caused by the tunneling effect, the thinning of film has a limit. Therefore, there progress studies of decreasing EOT using an insulation film having higher relative permittivity than that of silicon thermally oxidized film while increasing the physical film thickness than that of the silicon thermally oxidized film to suppress the leak current.

The insulation film with thin and uniform thickness to give high dielectric constant is formed by applying post-treatment after the deposition of the thin and uniform-thickness film, as described in Patent Document 1. As given in Patent Document 2, the deposition of thin and uniform-thickness film adopts a sputtering method and apparatus in which the target is inclined relative to the surface of the substrate, and the substrate is rotated. The technology provides the deposition of film having very thin and uniform thickness on a substrate even with a target having smaller diameter than that of the substrate. According to the description of Patent Document 2, a film having a thickness of about 1700 Å (170 nm) deposited on a substrate of 4 inch in diameter using a target of 2 inch in diameter gave film-thickness distribution of ±2.0% or less in a distance range of −40 mm to +40 mm around the center of the substrate, and the film having that thickness deposited on a substrate of 350 mm in diameter using a target of 9.3 inch in diameter gave film-thickness distribution of ±0.60% in a distance range of 160 mm from the center of the substrate.

Furthermore, a magnetic random access memory (MRAM) which is expected to be mounted on varieties of applications as the nonvolatile memory element mounts a magnetic tunnel junction (MTJ) element as a magnetoresistive element thereon. The MTJ has a basic structure of a thin tunnel-insulation film of about 1 nm of thickness, and two thin magnetic films sandwiching the tunnel-insulation film therebetween. In practical applications, however, the MTJ is composed of a multilayer film structured by metal films including an antiferromagnetic layer to generate spin-valve action, an underlayer, and a protective layer. For the detail of spin-valve action, refer to, for example, the description in Non-Patent Document 1.

For practical applications, as described in Patent Document 3, there is required the formation of a laminated structure of a thin and uniform-thickness magnetic film and an insulation film each having thicknesses from 1 nm or less to several nanometers. Also to obtain the MTJ element, there is adopted an inclined rotation sputtering method which is disclosed in Patent Document 2.

[Patent Document 1] Japanese Patent Laid-Open No. 2005-340721

### [Patent Document 2] Japanese Patent Laid-Open No. 2000-265263

### [Patent Document 3] Japanese Patent Laid-Open No. 2002-167661

[Non-Patent Document 1]“Magnetoresistive Head and Spin-Valve Head: 2nd Edition, Fundamental and Application” John C. Malinson, (translated by Kazuhiko Hayashi), Maruzen, (2002)

### DISCLOSURE OF THE INVENTION

### Problems to be Solved by the Invention

Regarding what is called the “inclined rotation sputtering”, or the sputtering technology which sputters a very thin film, 1 nm or less or 5 nm or less in thickness, requested for the semiconductor devices in recent years, using a target positioned in non-parallel to the rotating substrate, there has not been proposed a technology for depositing a film at a uniform thickness of 1% or smaller standard deviation (σ) of the intraplane distribution on a substrate having larger diameter than that of the target, such as 200 mm and 300 mm in diameter. In the process for depositing a gate insulation film of MOSFET as a silicon semiconductor apparatus of increased integration and increased performance, even using a single layer of HfSiO which has 1.2 nm or less of equivalent oxide thickness (SOT) and which is a typical high-dielectric-constant material, it is required to deposit the very thin film of practical thickness of 5 nm at a good uniformity in thickness in a zone of 280 mm in diameter on a substrate of 300 mm in diameter. If the uniformity in thickness of the gate insulation film is not good, there arises a problem of off-spec and of deteriorating production yield.

According to the film-deposition by the inclined-rotation sputtering method disclosed in Patent Documents 1 and 2, the intraplane uniformity in film thickness of a thin film of 1.2 nm or smaller EOT on the substrate gives a standard deviation (σ) of 4.8%, which value is not satisfactory for the requirement of the “technology node 45 nm generation”. As a result, the gate threshold voltage (Vₜₕ) of MOSFET becomes disperse, which raises a problem of not increasing the production yield of the semiconductor devices. The phenomenon of not-increasing the production yield of semiconductor devices suggests poor film thickness distribution of the gate insulation film.

For the MOSFET manufactured by the technology disclosed in Patent Document 1, the determined C-V characteristic shows good EOT and good leak current. Also Patent Document 1 reports that an apparatus having the same structure to above provides a good distribution of film thickness, or 0.95% of the standard deviation (σ), in a zone of 180 mm in diameter on the substrate of 200 mm in diameter. Although there is no clear description about the film thickness for determining the distribution of film thickness, considering that the film thickness distribution in Patent Document 1 adopts a method of calculating the film thickness based on the conversion from the observed values of sheet resistance, it is clear that the measurement is done at a thickness allowing measurement of the sheet resistance at a desired accuracy, or the measurement is done after a long period of deposition of film up to 10 nm or larger thickness.

Patent Document 2 describes the measurement result on a thick film as thick as 170 nm. Consequently, there has not been disclosed a technology of using the inclined-rotation sputtering to deposit a very thin film of 5 nm or less or 1 nm or less with uniform thickness giving 1% or smaller standard deviation (σ) of actual intraplane distribution on a large substrate of 200 mm or 300 mm in diameter.

In addition, for an MRAM mounting the MTJ element, expected to be mounted on varieties of applications as the nonvolatile memory element, it is necessary to actualize a multilayer film structure of a magnetic material and an insulation film, giving a single layer thickness ranging from 1 nm or less to several nanometers, in order to assure the interconnection resistance RA and to increase the magnetic resistance ratio (MR ratio). To actualize the MTJ element, it was found that the conventional technology gives a large dispersion of interconnection resistance and does not increase the production yield of semiconductor devices (MRAMs). Also for that case, the dispersion of interconnection resistance presumably comes from the nonuniformity in the film-thickness distribution on the tunnel insulation film and other structuring films.

Patent Document 3 describes an apparatus using the inclined-rotation sputtering technology to continuously deposit multilayer films. Although Patent Document 3 deposits films giving only 0.8 nm in thickness at the minimum, Patent Document 3 deals with a substrate smaller than the target, and does not disclose the degree of uniformity in the thickness of the actually deposited very thin film. Therefore, also Patent Document 3 does not disclose the technology of depositing very thin film uniformly on a large substrate using the inclined-rotation sputtering method.

### Means to Solve the Problems

The present invention solves the above problems, and provides a sputtering method and a sputtering apparatus, in which the target is positioned being inclined relative to the substrate placed on the substrate-placing table, while setting a condition of d≧D, where d is the diameter of the substrate holder, and D is the diameter of the target, and setting a condition of ten or more of the total number of rotations R of the substrate-placing table from the beginning of film-deposition on the substrate to the completion thereof.

Furthermore, the present invention provides a sputtering method and a sputtering apparatus, in which the rotational speed V of the substrate-placing table is controlled so that the total number of rotations R thereof may satisfy the formula of

0.95×S−0.025≦R≦1.05×S+0.025

at R≦10, where R is the total number of rotations of the substrate-placing table from the beginning of film-deposition on the substrate to the completion thereof, and S is the value of the number of total rotations R rounded off to integer.

Furthermore, it is preferred that the step of sputtering on the substrate is conducted under a condition of V≧60 rpm during the period of depositing film on the substrate, where V is the rotational speed of the substrate-placing table. In that case, it is preferable that the sputtering target face is positioned being inclined by [5°≦θ≦45°] relative to the substrate. Furthermore, it is preferable that a condition of [0.7≦T/W≦1.6] is set, where T is the distance between the center of the target of the target cathode and a plane including the substrate or the surface of the substrate-placing table, and W is the distance on a line, passing through the center of the target cathode and the normal b passing through the center of the substrate or the substrate-placing table. Also it is preferable that the distance T is [50 mm≦T≦800 mm], where T is the distance between the center of the target or the target cathode and the plane including the substrate or the surface of the substrate-placing table. Furthermore, the present invention provides an inclined-rotation multi-cathode sputtering method and an inclined-rotation multi-cathode sputtering apparatus in which a single treatment chamber contains one or more targets and one or more target cathodes.

### EFFECT OF THE INVENTION

According to the inclined-rotation multi-cathode sputtering apparatus of the present invention, in the gate insulation film deposition step for a MOSFET in a silicon semiconductor apparatus with increased integration and increased performance, a gate insulation film of a high-dielectric-constant material having 1.2 nm or smaller equivalent oxide thickness (EOT) at a good uniformity can be deposited giving 1.0% or less of standard deviation (σ) both for the film thickness and the composition even within a plane of a substrate of 300 mm in diameter. With the apparatus to suppress the dispersion of the gate threshold voltage (Vₜₕ) in MOSFET, the production yield of semiconductor devices can drastically be increased.

In addition, according to the inclined-rotation multi-cathode sputtering apparatus of the present invention, on depositing film of the MTJ element of MRAM, a very thin multilayer film having 1 nm or less to several nanometers of thickness of a single layer can be deposited at a good uniformity of both film thickness and composition. Thus also for the MTJ element, suppression of dispersion of the interconnection resistance (RA) and of the magnetic resistance rate (MR ratio) achieves a drastic improvement in the production yield of semiconductor devices (MRAM).

### BRIEF DESCRIPTION OF THE DRAWINGS

FIG. 1 shows a schematic drawing illustrating the relative positioning of substrate and target in a sputtering apparatus of the present invention.

FIG. 2 shows a schematic drawing illustrating the structure of a sputtering treatment chamber of the present invention.

FIG. 3 shows a schematic drawing illustrating the structure of a first multi-chamber apparatus of the present invention.

FIG. 4 is a graph giving the relation between the rotational speed and the uniformity in film thickness of HfN film deposited using the first multi-chamber apparatus of the present invention.

FIG. 5 is a graph giving the relation between the rotational speed and the threshold voltage of HfN film deposited using the first multi-chamber apparatus of the present invention.

FIG. 6 is a graph giving the relation between the rotational speed and the production yield of devices manufactured using the first multi-chamber apparatus of the present invention.

FIG. 7 is a graph giving the relation among the distance W, the distance T, and the uniformity in film thickness for the films deposited using the sputtering treatment camber illustrated in FIG. 1 and FIG. 2.

FIG. 8 is a graph giving the relation between the angle θ and the uniformity in the film thickness for the films deposited using the sputtering treatment camber illustrated in FIG. 1 and FIG. 2.

FIG. 9 is a graph giving the relation between the total number of rotations R and the uniformity in film thickness for the films deposited using the sputtering treatment camber illustrated in FIG. 1 and FIG. 2.

FIG. 10 illustrates the procedure of forming a hafnium oxynitride film (HfON) which is a high-dielectric-constant film on the basis of Hf, using the first multi-chamber apparatus of the present invention, and of forming a gate electrode composed of titanium nitride (TiN) thereon.

FIG. 11 is a schematic drawing illustrating the structure of a second multi-chamber apparatus of the present invention.

FIG. 12 illustrates the structure of MTJ manufactured using the second multi-chamber apparatus of the present invention.

FIG. 13 illustrates the manufacturing process of MTJ manufactured using the second multi-chamber apparatus of the present invention.

FIG. 14 is a graph giving the relation between the substrate rotational speed and the production yield of MTJ manufactured using the second multi-chamber apparatus of the present invention.

FIG. 15 illustrates the structure of MOSFET manufactured using the first multi-chamber apparatus of the present invention.

### DESCRIPTION OF THE REFERENCE SYMBOLS

A Center of target on the surface thereof
O Center of substrate on the surface thereof
B Point of intersection between the normal including the substrate center O on the surface thereof and the line including the center A and in parallel to the substrate face
Q Point of intersection between the normal a and the normal b
D Diameter of the target
d Diameter of the substrate
V Rotational speed of the substrate
T Vertical distance to the target
W Horizontal distance to the target
a Normal to the target, passing through the target center or the target cathode center
b Normal to the substrate, passing through the substrate center or the substrate holder center
θ Angle between the normal a and the normal b
11 Substrate holder
11a Rotational axis of the substrate holder
12 Substrate
21 Target cathode
22 Target
22a Rotational axis of the target
23 Magnet grouping
23a Rotational axis of the support plate
24 Support plate
31 Treatment chamber
32 Evacuation port
33,34 Gas-introducing means
35 Double shutter
36 DC power source
37 Servomotor
38 Rotational power-transmission mechanism
103,104 Load-lock chamber
106 Core chamber
107 Vacuum transfer robot
131 Arm of the vacuum transfer robot
132a,132b Hand of the vacuum transfer robot
120a,120b Gate valve
201 Degassing chamber
301,501 Annealing chamber
202,302,402,502,602 Substrate holder
203,303,403,503,603 Substrate
401,601 Sputtering apparatus chamber
404a-404d,604a-504d Target
113,114 Load-lock chamber
116 Core chamber
117,118 Vacuum transfer robot
120a-130g Gate valve
131 Arm of the vacuum transfer robot
132 Hand of the vacuum transfer robot
211 Cleaning chamber
611 Oxidation treatment chamber
212,312,512,612,712 Substrate holder
213,313,513,613,713 Substrate
311,511,711 Sputtering apparatus Chamber
314a-314e, 514a-514d,714a-714e Target
1501 P-type silicon substrate
1502 Drain electrode
1503 Source electrode
1504 High-dielectric-constant layer
1505 Gate electrode
1506 Inversion layer domain
1511 Drain electrode lead wire
1512 Source electrode lead wire
1513 Gate electrode lead wire

### BEST MODE FOR CARRYING OUT THE INVENTION

### Example 1

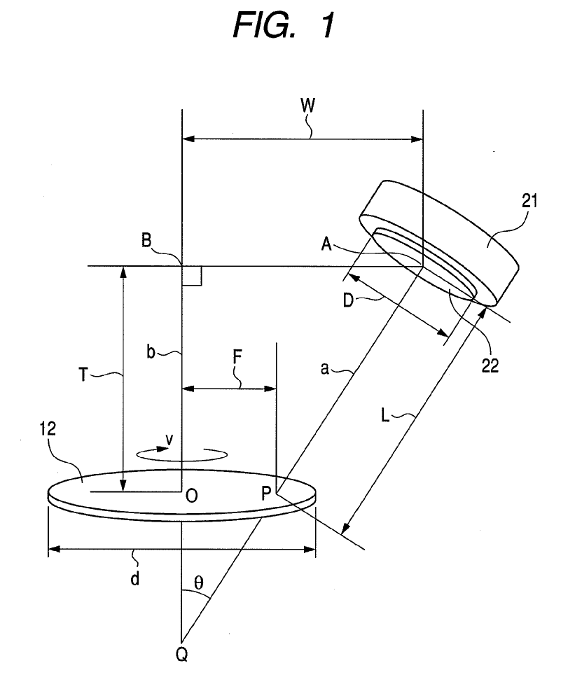

The first embodiment of the present invention will be described below referring to FIGS. 1 to 9. FIG. 1 illustrates the relative positioning of a target 22 and a substrate 12 of the sputtering apparatus to actualize the present invention. The symbol A is the center of surface of the target 22 placed on a target cathode 21. The symbol O is the center of surface of the substrate 12. The symbol B is the point of intersection between a normal to the surface of the substrate 12, including the center O of the substrate 12, and a line including the center A and being in parallel to the surface of the substrate 12. The symbol a is the normal to the surface of the target 22 passing through the center of the target or the center of the target cathode. The symbol b is the normal to the surface of the substrate 12 passing through the center of the substrate or the center of the substrate holder. The symbol 9 is the angle between the normal a and the normal b intersecting each other. The symbol Q is the point of intersection between the normal a to the surface of the target 22 and the normal b to the surface of the substrate 12. Te symbol D is the diameter of the target 22. The symbol d is the diameter of the substrate 12. The symbol V is the rotational speed of the substrate 12. The symbol T is the vertical distance between the center A of the target and the center O of the substrate. The symbol W is the horizontal distance between the center A of the target and the center O of the substrate. The symbol P is the point of intersection between the normal a and the substrate 12. The symbol F is the horizontal distance between the point P and the center O of the substrate. The symbol L is the distance between the center A of the target and the point P.

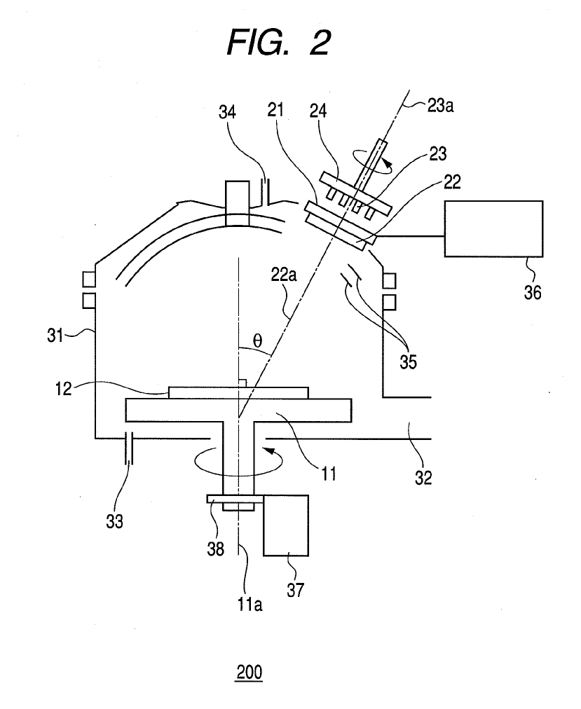

Example 1 applies the sputtering method and the sputtering apparatus of the present invention to the manufacture of MOSFET which is a semiconductor element. The sputtering method and apparatus are used in a step of the process for forming a MOSFET gate insulation layer on a silicon substrate in the sputtering treatment chamber. The description begins with the structure of a sputtering treatment chamber 200 of the present invention referring to FIG. 2. The treatment chamber 200 is made of aluminum, and has the target 22 attached to the target cathode 21. The target 22 is positioned to be non-parallel to a substrate holder 11. The diameter of the target 22 is preferably the same as or smaller than that of the substrate holder 11. Example 1 uses the target 22 of 164 mm in diameter. As for the film-deposition performance of the sputtering apparatus of the present invention, the uniformity in the film thickness shows no significant improvement even when the diameter of the target is larger than the diameter of the substrate. When the target diameter is increased, there rather arises a problem of increasing in the target price, and when pluralities of targets are installed, a problem arises to limit the number of targets allowed to be installed in a single chamber. The target 22 is mounted on the target cathode 21. At rear side of the target cathode 21, there is a magnet grouping 23 (a group of permanent magnets) fixed to a rotatable support plate 24. The support plate 24 has a drive mechanism (not shown), and the magnet grouping 23 is driven by a servomotor in the drive mechanism to rotate around a rotational axis 23a of the support plate. To the target 22, a DC power is supplied from a DC power source 36 to generate plasma. The substrate holder 11 rotates around a rotational axis 11a of the substrate holder, and rotates the substrate 12 placed on the substrate holder 11. The substrate holder 11 is brought to rotate during a period of film-deposition on the substrate 12 by a servomotor 37 and a rotational power-transmission mechanism 38, positioned outside the treatment chamber 200. A chamber 31 is evacuated by an evacuation system composed of a turbo-molecular pump and a drive pump (both are not shown) via an evacuation port 32. The chamber 31 allows argon (Ar) gas and nitrogen (N₂) gas to be introduced into the treatment chamber via gas-introducing means 33 and 34. A double shutter 35 is opened only during the film-deposition treatment period, and is closed in other period, in order to secure the film-deposition performance on depositing very thin film. The symbol θ is the angle between the rotational axis 22a of the target 22 and the rotational axis 11a of the substrate holder 11.

The treatment chamber 200 has the substrate holder 11 of 400 mm in diameter, thereby allowing the silicon substrate 12 of 300 mm in diameter to be placed thereon. During the period of film-deposition on the substrate 12, the substrate holder 11 is rotated by the servomotor 37 via the rotational power-transmission mechanism 38, (both are positioned outside the vacuum treatment chamber; not shown). Even in a process of depositing very thin film (1 nm or less and 5 nm or less of thickness) and of high film-deposition speed, the rotational speed can be conditioned and applied so as to obtain 10 or more of the total number of rotations of the substrate-placing table from the beginning of film-deposition on the substrate to the completion thereof. In that case, the total number of rotations of the substrate-placing table from the beginning of film-deposition on the substrate to the completion thereof is preferably 10 or more.

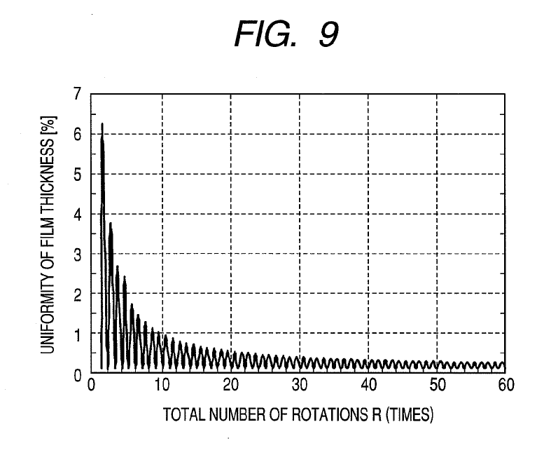

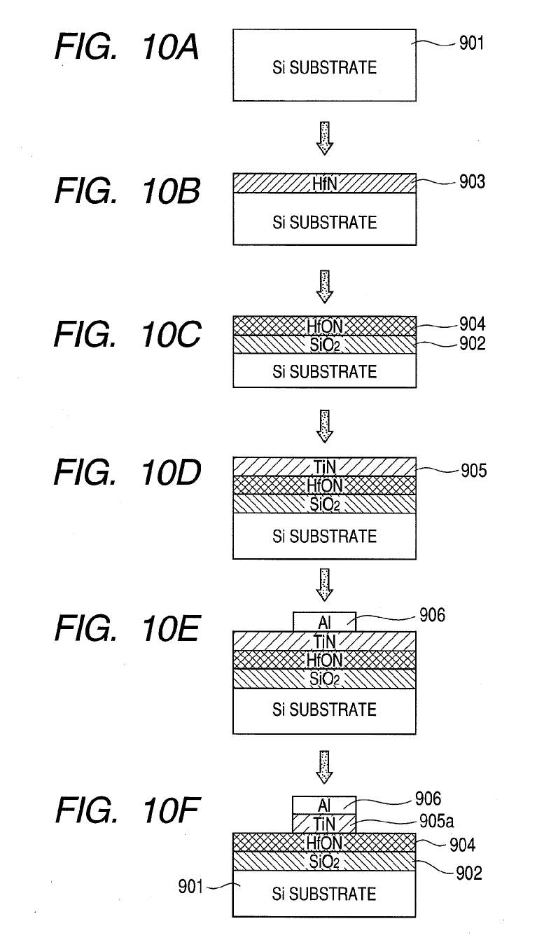

The relation between the total number of rotations of the substrate-placing table from the beginning of film-deposition on the substrate to the completion thereof and the uniformity of film thickness is investigated. The result of the investigation will be described below referring to FIG. 9. The present invention is an inclined directional sputtering technology, thus basically the distribution of thickness of the deposited film at a certain moment becomes nonuniform in a plane of the substrate. By, however, rotating the substrate, a distribution of good uniformity in thickness can be attained. An experiment conducted on the matter will be described. The apparatus applied was the same as that of this Example 1, using a substrate of 300 mm in diameter. The operating condition was 0.019 Pa of pressure, 20 sccm of argon (Ar) gas flow rate, 6 sccm of nitrogen (N₂) gas flow rate, 300 W of DC power, and 12.5 sec of film-deposition time. A hafnium nitride (HfN) film was deposited on the substrate. The distribution of film thickness was determined at 49 positions distributed in a plane of 280 mm in diameter. The film thickness was measured by an Ellipsometer. In FIG. 9, the horizontal axis is the total number of rotations of the substrate, and the vertical axis is the uniformity of film thickness σ [%]. The uniformity of film thickness σ [%] is derived by the formula:

The uniformity of film thickness σ [%]=(Standard deviation/Average)×100 [%]

As shown in FIG. 9, it was found that the uniformity of thickness of film deposited by the inclined rotation sputtering repeats periodical fluctuation at every rotation of the substrate. That is, the uniformity of film thickness becomes minimum (better) at the integral multiple of rotations, or at the point of [360°×n], (n is a natural number not including 0), counted from the beginning of film deposition, and the uniformity thereof becomes maximum (poor), at the point of [(integral multiple)+0.5 rotation], or [360°×n+180°] (n is a natural number not including 0). It was also found that the magnitude of fluctuations of the uniformity decreases with increase in the total number of rotations, as given in FIG. 9. For example, at the total number of rotations of 1 to 2, the uniformity in thickness is 6.3% at the maximum. However, the uniformity in thickness is 0.93% at the maximum at 10 to 11 rotations, and 0.52% at the maximum at 20 to 21 rotations.

The total number of rotations is expressed by: [The total number of rotations=(Rotational speed)×(film-deposition time)]. The film-deposition time is expressed by: [The film-deposition time=(Film thickness)÷(Film-deposition speed)]. From the necessity of forming a thinner film than conventional ones, the film-deposition time becomes short, which decreases the total number of rotations during film-deposition period. The uniformity of film thickness in the case of small total number of rotations gives a large fluctuation magnitude depending on the total number of rotations as described above. Thus when that condition is applied to deposit a thin film, poor film-thickness distribution often appears. Therefore, to attain the desired level of 1% or less of uniformity, it is necessary to assure 10 or more of the total number of rotations R from the beginning of film-deposition to the completion thereof. To achieve the desired level of 1% or less of uniformity in the case of 10 or less of the total number of rotations R, it is necessary for the total number of rotations R to satisfy the formula of

0.95×S−0.025≦R≦1.05×S+0.025

where S is the value of the number of total rotations R rounded off to integer.

For example, under the conditions of 12.5 sec of film-deposition time and S=1, the calculation of [0.95−0.025≦R≦1.05+0.025] gives that the film-deposition completes at the total number of rotations R of [0.925≦R≦1.075] after beginning the film-deposition. The film-deposition time of 12.5 sec gives that the film-deposition is conducted in a period of 12.5 sec by adjusting the rotational speed V of [0.925/(12.5/60) rpm≦V≦1.075/(12.5/60) rpm], or [4.44≦rpm≦V 5.16 rpm].

For example, under the conditions of 15 sec of film-deposition time and S=9, the calculation of [0.95×9−0.025≦R≦1.05×9+0.025] gives that the film-deposition completes at the total number of rotations R of [8.525≦R≦9.475] after beginning the film-deposition. The film-deposition time of 15 sec gives that the film-deposition is conducted in a period of 15 sec by adjusting the rotational speed V of [8.525/(15/60) rpm≦V≦9.475/(15/60) rpm], or [34.1 rpm≦V≦37.9 rpm].

Furthermore, substantially 60 rpm or more is preferred.

The chamber 31 in FIG. 2 is evacuated by an evacuating means composed of a turbo-molecular pump and a drive pump (both are not shown) via the evacuation port 32. It is not important to combine the turbo-molecular pump with the drive pump in the evacuating means. Applicable evacuating means is arbitrary if only the desired vacuum is attained, and other pump such as criopump may be used. The gas-introducing means 33 and 34 allows feeding argon (Ar) gas and nitrogen (N₂) gas to the treatment chamber 31. The internal pressure of the treatment chamber 31 during the period of sputtering treatment is monitored by a diaphragm vacuum meter (not shown) via a port (not shown), which allows monitoring inside the chamber. The target 22 is positioned inclining relative to the silicon substrate 12 placed on the substrate holder 11, thereby allowing containing pluralities of targets in the chamber 31 at the same time. Example 1 mounts four target cathodes. The rotational axis 11a of the substrate holder 11 and the rotational axis 22a of the target 22 intersect with each other at a specified angle θ, and both the rotational axis 11a and the rotational axis 22a exist in the same plane. The angle θ between the rotational axis 11a and the rotational axis 22a is preferably in a range of [5°≦0≦45°].

FIG. 8 shows an observed relation between the angle θ and the uniformity in thickness (%). Since the distribution deteriorates at excessively large θ and at excessively small θ, practically θ is preferably in a range of [5°≦θ≦45°]. Example 1 adopts an arrangement to attain θ=30°. The target cathode 21 and the target 22 given in FIG. 2 are electrically insulated from the treatment chamber 31 and other parts by an insulator (not shown). At upper face or side face of the target 22 and the target cathode 21, there is placed the magnet grouping 23 made of permanent magnets fixed to the rotatable support plate 24. The support plate 24 has a driving means (not shown). During the operational period of the apparatus, the driving means rotates the magnet grouping 23 around the rotational axis of the support plate 23a. The double shutter 35 is opened only during the film-deposition treatment, and is closed in other period, in order to secure the film-deposition performance on depositing a very thin film.

Referring to the relative positioning of the target 22 and the substrate 12, shown in FIG. 1, it is preferable to set a condition of [0.5≦T/W≦1.8], or [0.7≦T/W≦1.6], where T is the distance between the center A of the target 22 or the target cathode 21 and a plane including the surface of the substrate 12 or the substrate holder 11, and W is the minimum distance between the center A of the target cathode 21 and the normal b passing through the center O of the substrate 12 or the substrate holder 11.

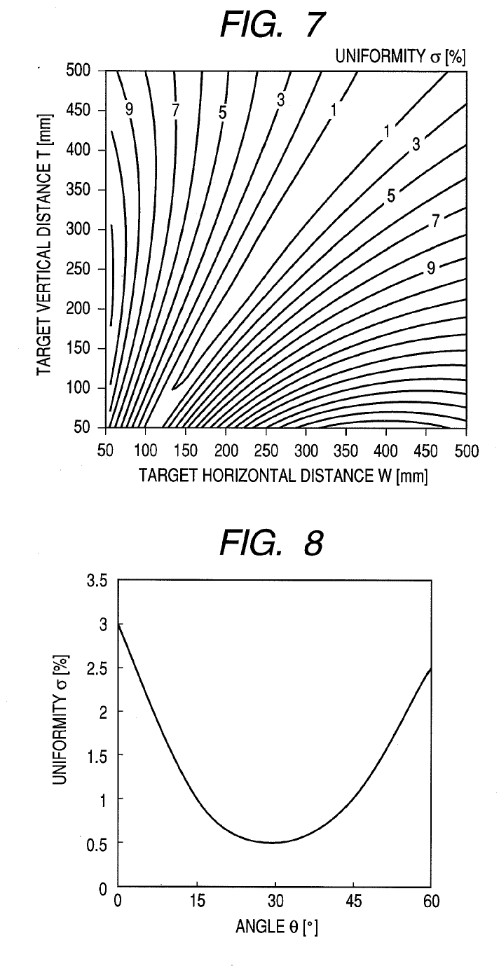

FIG. 7 shows an investigation result of the relation among the distance T, the distance W, and the deposited-film thickness distribution. As seen in FIG. 7, the film-thickness distribution mostly depends on the ratio of the distance T to the distance W, giving good film-thickness distributions in an approximate range of [0.5≦T/W≦1.8] in practical point of view, or giving good film-thickness distributions in an approximate range of [0.7≦T/W≦1.6] in practical point of view. Example 1 adopts a condition of T/W=1.1.

It is preferable that the distance T between the center A of the target 22 or the target cathode 21 and a plane including the surface of the substrate 12 or the substrate holder 11 is in a range of [50 mm≦T≦800 mm] because, as shown in FIG. 7, excessively short T deteriorates the distribution, and excessively long T decreases the film-deposition speed. Example 1 adopts the distance T as 300 mm.

To the target 22, a DC power is supplied from the DC power source 36 to generate plasma. Use of DC power is, however, not the essential matter. Instead of DC power, alternating current (RF) may be used to generate plasma.

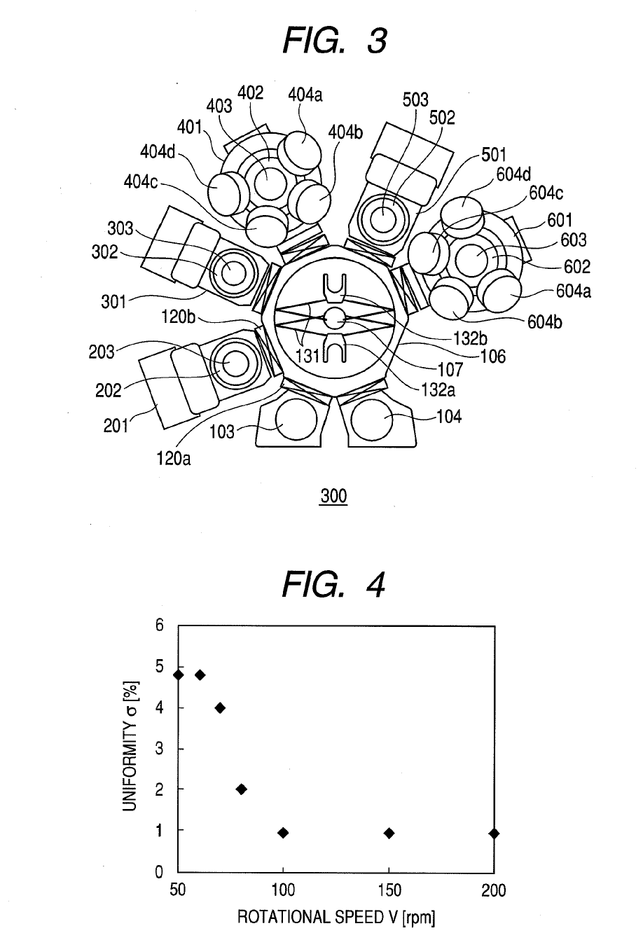

FIG. 3 shows a schematic drawing illustrating the structure of a multi-chamber apparatus 300 of Example 1. The apparatus for manufacturing semiconductor element 300 of Example 1 is a cluster type, having pluralities of sputtering apparatus chambers. A core chamber 106 equipped with a vacuum transfer robot 107 is positioned at the center of the multi-chamber apparatus 300. The vacuum transfer robot 107 has a telescopic arm 131 and hands 132a and 132b for mounting the substrate. The root of the arm 131 is rotatably attached to the core chamber 106. The core chamber 106 has load-lock chambers 103 and 104. The load-lock chambers 103 and 104 allow the treating substrate to enter the apparatus for manufacturing semiconductor element 300 from outside and allow the substrate subjected to the film-deposition to be transferred outside from the apparatus for manufacturing semiconductor element 300. Two load-lock chambers are installed to increase the productivity by using them alternately.

Around the core chamber 106, there are arranged two sputtering apparatus chambers 401 and 601, two annealing chambers 301 and 501, and one degassing chamber 201. Between the core chamber and each treatment chamber, there is installed a gate valve 120 which isolates both chambers from each other and which opens/closes at need. For example, FIG. 3 shows a gate valve 120a installed between the load-lock chamber 103 and the core chamber 106, and a gate valve 120b installed between the degassing chamber 201 and the core chamber 106. Also between other treatment chamber and the core chamber 106, a gate valve having similar structure to that of the gate valves 120a and 120b is installed. Although each chamber is provided with a vacuum evacuating means, a gas-introducing means, a power supplying means, and the like, they are not shown in FIG. 3. Each of the sputtering apparatus chambers 401 and 601 of the apparatus for manufacturing semiconductor element 300 given in FIG. 3 is the sputtering apparatus 200 provided with the present invention given in FIG. 2.

The degassing chamber 201 has a substrate holder 202 that holds a substrate 203. Similarly, annealing chambers 301 and 501 have substrate holders 302 and 502, respectively. The substrate holders 302 and 502 hold the substrates 303 and 503, respectively.

In the sputtering apparatus chamber 401, a Hf target 404a is positioned at the ceiling part thereof to be non-parallel relative to a substrate 403 positioned on a substrate holder 402 at the bottom center of the chamber via a target cathode (not shown in FIG. 3). In the sputtering apparatus chamber 601, a Ti target 604a is positioned at the ceiling part thereof to be non-parallel relative to a substrate 603 positioned on a substrate holder 602 at the bottom center of the chamber via a target cathode (not shown in FIG. 3). In Example 1, the sputtering apparatus chamber 401 has four target cathodes, allowing mounting four targets 404a, 404b, 404c and 404d at a time. Similarly, the sputtering apparatus chamber 601 has four target cathodes, allowing mounting four targets 604a, 604b, 604c and 604d at a time.

Following is the description about the experiment which confirmed the relation between the substrate rotational speed V and the film-thickness distribution. The description begins in detail with the method for depositing a thin film on a substrate 403 referring to FIG. 2, executed in the sputtering apparatus chamber 401 of the multi-chamber apparatus 300 given in FIG. 3. On describing about the sputtering apparatus chamber 401 given in FIG. 3 of a schematic drawing of the multi-chamber according to Example 1 by replacing with FIG. 2 which is a schematic drawing of the sputtering treatment chamber, the target 22 of FIG. 2 is made of Hf, and the substrate 12 is made of doped silicon (p-Si, n-Si). The hafnium nitride (HfN) film which is the starting film to obtain the hafnium oxynitride (HfON) film as a high-dielectric-constant film is formed on the surface of the substrate 12 of doped silicon (p-Si, n-Si). Argon and N₂ are fed to the treatment chamber 31 as the process gases via the gas-introducing means 33 and 34. The internal pressure of the treatment chamber 31 is preferably kept to lower than 0.5 Pa. The target 22 adopts hafnium (Hf), and the sputtering is conducted by applying 300 W DC power thereto. To execute the sputtering using the target 22, the treatment chamber 31 is preliminarily charged with a mixed gas of nitrogen (N₂) and argon (Ar). Since N₂ atoms exist in the treatment chamber 31, the sputtered Hf atoms react with the radical/ion of nitrogen to form a film or a layer of hafnium nitride (HfN) on the surface of the substrate 12. The substrate 12 is made of silicon. The HfN film is formed on the doped silicon layer. During the period of sputtering using the target 22 to deposit the HfN film on the substrate 12, the substrate holder 11 rotates around the center axis 11a, thus rotating the substrate 12 placed on the substrate holder 11.

Next, the description is given about the procedure of forming the hafnium oxynitride (HfON) film as a high-dielectric-constant dielectric film based on Hf, and then of forming the gate electrode made of titanium nitride (TiN) thereon. FIG. 10 illustrates the process. First, FIG. 10A is described. (1) The substrate is rinsed with a diluted HF solution (hydrofluoric acid:water=1:50) to remove silicon natural oxide existed on the surface of the substrate. (2) The substrate is dried in a spin-drier. (3) The substrate is placed in the multi-chamber apparatus 300 given in FIG. 3. (4) The load-lock chamber 103 is evacuated. (5) The vacuum transfer robot 107 transfers the substrate from the load-lock chamber 103 to the degassing chamber 201, where the substrate is heated to 300° C. for 180 seconds, thus removing impurities such as water existed in the substrate. The substrate after treatment is shown in FIG. 10A as a Si substrate 901.

Next, the FIG. 10B is described. (6) The Si substrate 901 treated in the degassing chamber 201 is transferred to the sputtering apparatus chamber 401, where a HfN film 903 is deposited to 0.5 nm of thickness on the Si substrate 901 under the operating conditions of 0.019 Pa of pressure, 20 sccm of argon (Ar) gas flow rate, 6 sccm of nitrogen (N₂) gas flow rate, 300 W of DC power, 12.5 sec of film-deposition time, while rotating the substrate in a range from 50 to 200 rpm of the rotational speed, or in a range from 10.4 to 41.6 of the total number of rotations.

Next, the FIG. 10C is described. The substrate treated in the sputtering apparatus chamber 401 is transferred to the annealing chamber 501, where the substrate is annealed under atmospheric pressure of N₂ gas containing 1% of oxygen at 600° C. for 30 seconds, thus forming an HfON film 904. In this stage, the oxygen passing through the HfON film reacts with the Si substrate to form a very thin SiO₂ layer 902 at the Si/HfON interface.

Next, the FIG. 10D is described. The substrate treated in the annealing chamber 501 is further transferred to the sputtering apparatus chamber 601 of the multi-chamber apparatus provided with the present invention, where a titanium nitride (TiN) film 905 to be the gate electrode is deposited to a thickness of 10 nm under the mixed atmosphere condition of argon gas with nitrogen gas, described in the HfN film-deposition step.

Next, the FIG. 10E is described. The substrate treated in the sputtering apparatus chamber 601 is further transferred from the multi-chamber apparatus provided with the present invention via the load-lock chamber 104, and Al is deposited on the substrate by mask sputtering, thus forming an Al pad 906 of 100 μm square for measurement to a thickness of 50 nm. The pad is formed on each of 49 positions dispersed on the whole surface of a circular surface area of 280 mm of diameter relative to the substrate of 300 mm in diameter.

Next, the FIG. 10F is described. The substrate having the Al pad 906 formed thereon is further treated by wet-etching the TiN 905 by hydrogen peroxide (H₂O₂) aqueous solution using the Al pad 906 as the mask, thus forming a TiN gate electrode 905a.

FIG. 15 illustrates the structure of a MOSFET 1500 containing the high-dielectric-constant film manufactured by the multi-chamber apparatus 300 given in FIG. 3 of Example 1. On a p-type silicon substrate 1501, there are formed an n+ drain electrode 1502, an n+ source electrode 1503, and an inversion layer (channel) domain 1506. On the inversion layer domain 1506, there is positioned a high-dielectric-constant layer 1504 (HfON/SiO₂ layer) formed by the present invention. On the high-dielectric-constant layer 1504, a metal electrode TiN (or other metal) is formed as a gate electrode 1505. To the drain electrode 1502, the source electrode 1503, and the gate electrode 1505, a drain electrode lead wire 1511, a source electrode lead wire 1512, and a gate electrode lead wire 1513 are connected, respectively.

Following is the description about the method for evaluating the electric characteristics of MOSFET having the HfON film which is deposited by the above procedure using the multi-chamber apparatus provided with the sputtering method and apparatus of the present invention. The electric characteristics were determined by bringing the pad to contact with the probe, and by varying the bias-voltage from +2.0 V to −1.5 V at 1 MHz of frequency using a capacity-voltage meter (C-V meter), thus measuring the C-V characteristic to determine the electric characteristics such as threshold voltage (Vₜₕ).

Next, the description is given about the experimental result of varying the rotational speed of substrate. The description begins with the uniformity of thickness of the HfN film deposited using the sputtering method and the apparatus 200 given in FIG. 2. FIG. 4 shows the uniformity (%) of the HfN film thickness against the substrate rotational speed V (rpm), which film was deposited to 0.5 nm in thickness on the substrate of 300 mm in diameter. The film thickness was determined at 49 positions dispersed over the whole area of circular surface of 280 mm in diameter. As shown in FIG. 4, the uniformity (σ) giving the dispersion of film thickness was 4.8% at 50 rpm of substrate rotational speed, or at 10.4 rotations of the total number of rotations. However, the uniformity of film thickness (σ) was improved to 0.95% at 100 rpm of substrate rotational speed, or at 20.8 rotations of the total number of rotations. Furthermore, when the substrate was rotated at a high speed to 200 rpm, or up to 41.6 rotations of the total number of rotations, the standard deviation (σ) of the film thickness was 0.94%, which is almost the same as that for the case of 100 rpm of the substrate rotational speed. Thus, it was found that the uniformity of film thickness within the face area of the silicon substrate of 300 mm in diameter becomes very uniform at a region of approximately more than 60 rpm of the rotational speed, or above about 12.5 rotations of the total number of rotations. Similarly, also for the TiN film, the technology improves the uniformity of the film thickness.

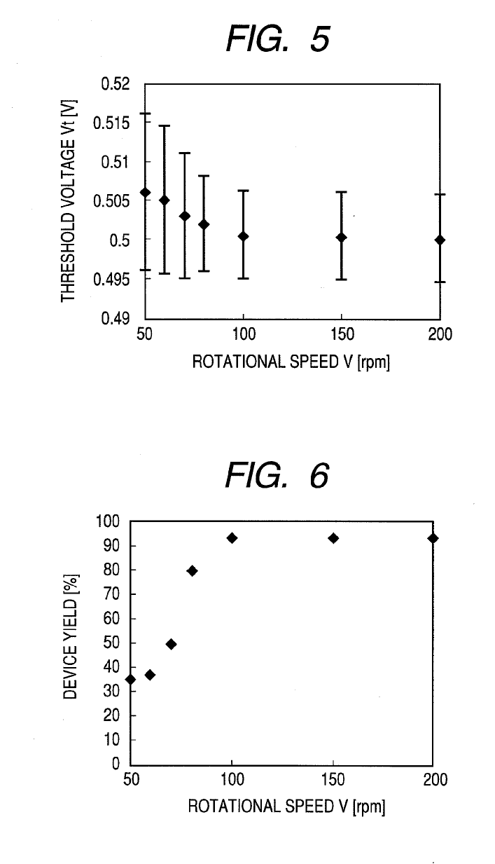

The description is then given about the observed electric characteristics for the case of using the process for the multi-chamber apparatus 300 given in FIG. 3, including the film-deposition step in the treatment chamber 200 given in FIG. 2 under the above-described procedure and conditions of FIG. 10. The results are shown in FIG. 5 and FIG. 6. In FIG. 5, the horizontal axis is the substrate rotational speed V (rpm), and the vertical axis is the threshold voltage (Vₜₕ). In FIG. 6, the horizontal axis is the substrate rotational speed V (rpm), and the vertical axis is the device production yield (%). As shown in FIG. 5, at 50 rpm of the substrate rotational speed, the intraplane dispersion of Vₜₕ of the substrate is large ranging from 0.496 V to 0.516 V. In a range of substrate rotational speed of larger than 60 rpm, however, the dispersion becomes small, improving to a range from 0.495 to 0.506 V at 100 rpm. As for the production yield of devices, FIG. 6 shows that, although the yield to satisfy the range of 0.5 V±0.005 V, which is the requirement, was about 35% at 50 rpm, the yield improved in a region of substrate rotational speed of larger than 60 rpm, giving a range from 0.495 V to 0.506 V at 100 rpm of the substrate rotational speed, and the yield satisfying the required range of 0.5 V±0.005 V was about 94%. These figures showed that the device production yield significantly improves in a range of substrate rotational speed of larger than 60 rpm.

Instead of hafnium (Hf) used in Example 1, other metals or metal nitrides can be used as the starting film to obtain the gate dielectric. Other metals are specific elements belonging to Group 3, Group 4, or Group 5 of the Periodic Table. Examples of the specific elements are metal such as Zr, La, Ti, and Ta, and a metal nitride thereof. When the specific elements are generally expressed by a symbol “A”, the nitride deposited is expressed as AxNy. The specific element (A) and nitrogen (N) in a nitride film (AxNy) has a ratio preliminarily determined between x and y. In detail, the y is smaller than the stoichiometric value for the nitride (AxNy) film.

Example 1 forms the high-dielectric-constant dielectric film on the surface of the doped silicon (p-Si, n-Si) substrate 12. However, the substrate for forming the high-dielectric-constant dielectric film may adopt a doped silicon compound (such as doped SiGe, or p-SiGe, n-SiGe) instead of the doped silicon.

Since Example 1 uses sole Hf metal as the metal of starting film which can become the high-dielectric-constant film, only one target cathode is applied. If, however, pluralities of metal laminate layer films or composite films are required, there may be used pluralities of target cathodes equipped with the respective targets. That is, aiming to improve the desired characteristics of the high-dielectric-constant film, for example, separate or simultaneous use of pluralities of targets in an apparatus having pluralities of target cathodes may deposit the laminate films or composite films as the starting films to obtain the high-dielectric-constant films.

Example 1 deposits the metal nitride film using Ar as the inert gas and N₂ gas as the reactive gas. However, good film-thickness distribution can be attained also by depositing the metal film using a metal target or an alloy target and introducing the inert gas to the chamber similar to that of the metal nitride film. The high-dielectric-constant film can be deposited by applying oxidation and nitrification after depositing the metal film at good uniformity in thickness.

Similarly, the metal oxide film may be deposited by introducing only the inert gas to the chamber while using a metal oxide target. Also this case provides good film-thickness distribution.

The use-object is not limited to the deposition of high-dielectric-constant film or of starting film to obtain the high-dielectric-constant film, and other applications can be given such as other metals, alloys, and metal-containing films for protective film, gate, and the like.

An investigation was given on the improvement in the device production yield by increasing the substrate rotational speed to 60 rpm or more. The result is described below referring to FIG. 9. FIG. 9 is a graph giving the relation between the total number of rotations R and the uniformity in film thickness (%) for the films deposited using the treatment camber 200 illustrated in FIG. 2. As described before, the present invention is an inclined directional sputtering film-deposition technology, thus basically the distribution of thickness of the deposited film at a certain moment becomes nonuniform in a plane of the substrate. By, however, rotating the substrate, a distribution of good uniformity in thickness can be attained. The matter significantly contributes to the improvement in the distribution of film thickness and in the device production yield at 60 rpm or higher substrate rotational speed. From the necessity of depositing thinner film than conventional ones, the film-deposition time becomes short, thus decreasing the total number of rotations during the film-deposition period. The uniformity of film thickness in the case of small total number of rotations gives a large fluctuation magnitude depending on the total number of rotations as described above. Thus when that condition is applied to deposit a thin film, poor film-thickness distribution often appears. Also in Example 1, the film-deposition time was as short as 12.5 sec to deposit a film of 0.5 nm in thickness, and even when the rotation was done at the rotational speed of 50 rpm, the number of rotations reached to only 10.4. Consequently, the distribution in film thickness was poor, at near 5%. On the other hand, when the rotational speed increased to 100 rpm, the total number of rotations became 20.8. As seen in FIG. 9, the uniformity (%) of film thickness at the poorest range between about 10 rotations and about 20 rotations decreased to about half. That large difference presumably came from the stopping of the rotation at a point somewhat near to the integral multiple of the number of rotations. Although the values of uniformity differ between FIG. 9 and FIG. 4, the difference came from the different conditions of film-deposition, thus the difference has no significance. The trend of dependency of the uniformity on the total number of rotations is the same for both figures. To avoid that non-uniformity, there are two applicable methods as described before. The one is to bring the total number of rotations R to 10 or more from the beginning of film-deposition to the completion thereof. The other is to control the rotational speed V of the substrate-placing table so that the total number of rotations R thereof may satisfy the formula of

0.95×S−0.025≦R≦1.05×S+0.025

at R≦10, where R is the total number of rotations of the substrate-placing table from the beginning of film-deposition on the substrate on the substrate-placing table to the completion thereof, and S is the value of the number of total rotations R rounded off to integer. Although the total number of rotations from the beginning of film-deposition to the completion thereof is substantially important, it is very effective, as understood by Example 1, to increase the rotational speed to increase the total number of rotations during the film-deposition period. According to Example 1, the rotational speed of 60 rpm or more gives large effect to attain the target value of 1% or less of the uniformity of film thickness.

### Example 2

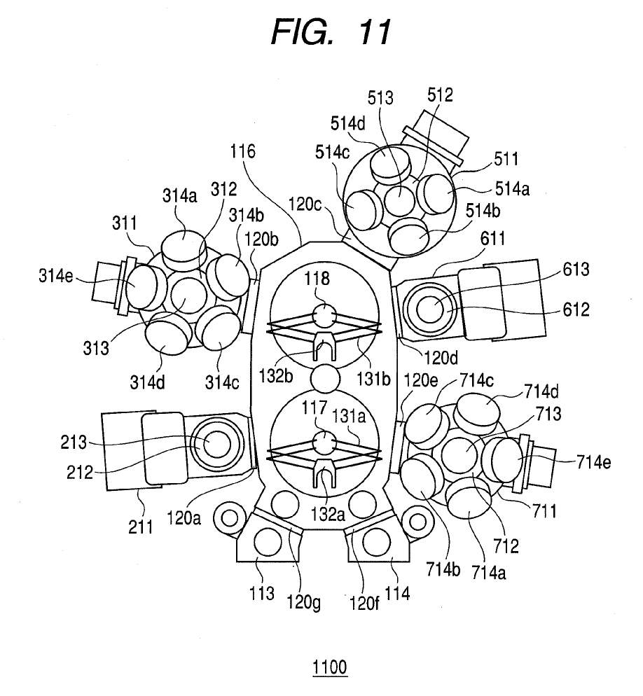

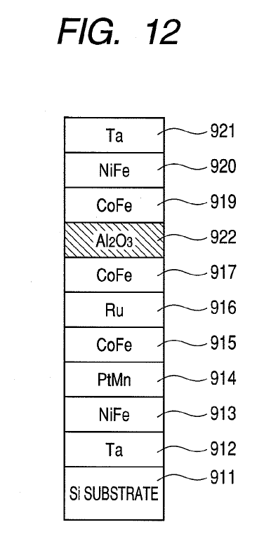

The second embodiment of the present invention will be described below referring to FIGS. 11 to 15. The second embodiment relates to forming an MTJ structure which is a magnetoresistive element used in MRAM and the like. Example 2 forms an MTJ having the structure illustrated in FIG. 12. The MTJ has a basic structure of a thin tunnel insulation film of about 1 nm in thickness and two thin magnetic films sandwiching the same. As a practical structure, the MTJ is made of a multilayer film composed of metallic films such as an antiferromagnetic layer to generate spin-valve action, an underlayer, and a protective layer. For the spin-valve action, detail description is given in, for example, “Magnetoresistive Head and Spin-Valve Head: 2nd Edition, Fundamental and Application” John C. Malinson, (translated by Kazuhiko Hayashi), Maruzen, (2002).

FIG. 11 is a schematic drawing illustrating the structure of a multi-chamber 1100 in Example 2, mounting the sputtering apparatus of the present invention. The magnetic multilayer film-manufacturing apparatus 1100 is cluster type, having pluralities of sputtering apparatus chambers. A core chamber 116 equipped with vacuum transfer robots 117 and 118 is installed at the center of the magnetic multilayer film-manufacturing apparatus 1100. The vacuum transfer robots 117 and 118 have telescopic arms 131a and 131b and the hands 132a and 132b for mounting the substrate, respectively. The root of each of the arms 131a and 131b is rotatably attached to the core chamber 116. The core chamber 116 of the magnetic multilayer film-manufacturing apparatus 1100 given in FIG. 11 has load-lock chambers 113 and 114. The load-lock chambers 113 and 114 allow the treating substrate to enter the magnetic multilayer film-manufacturing apparatus 1100 from outside and allow the substrate subjected to the deposition of magnetic multilayer film to be transferred from the magnetic multilayer film-manufacturing apparatus 1100. Between the core chamber 116 and each of the load-lock chambers 113 and 114, there are installed the respective gate valves 120g and 120f which isolate the load-lock chamber from the core chamber and which open/close at need. Two load-lock chambers are installed to increase the productivity by using them alternately.

In the magnetic multilayer film-manufacturing apparatus 1100 shown in FIG. 11, there are arranged three sputtering apparatus chambers 311, 511 and 711, one oxidation treatment chamber 611, and one cleaning chamber 211 around the core chamber 116. Between the core chamber 116 and each of the treatment chambers, there are installed the respective gate valves 120a to 120e which isolate the respective treatment chambers from the core chamber 116 and which open/close at need. Although each chamber is provided with a vacuum evacuating means, a gas-introducing means, a power supplying means, and the like, they are not shown in FIG. 11. Each of the sputtering apparatus chambers 311, 511 and 711 of the magnetic multilayer film-manufacturing apparatus 1100 shown in FIG. 11 is a sputtering apparatus chamber to continuously deposit pluralities of films constituting the magnetoresistive elements within the same chamber. Each of the sputtering apparatus chambers 311, 511 and 711 of the magnetic multilayer film-manufacturing apparatus 1100 shown in FIG. 11 is the sputtering apparatus 200 provided with the present invention given in FIG. 2. The basic structure is the same as that of Example 1 shown in FIG. 2. Since continuous deposition of thin multilayer films is required, in principle, pluralities of targets and target cathodes are provided and used in one chamber.

In the sputtering apparatus chamber 311, targets 314a, 314b, 314c, and 314d of Ta, NiFe (Ni:Fe=80:20), PtMn (Pt:Mn=50:50), and CoFe (Co:Fe=90:10) are positioned at the ceiling part thereof via the respective target cathodes (not shown) relative to the substrate 313 placed on the substrate holder 312 at the bottom center of the chamber, respectively. As illustrated in FIG. 11, the sputtering apparatus chamber 311 also allows mounting a target 314e, and the target 314e can be appropriately used depending on the use mode. Between the core chamber 116 and the sputtering apparatus chamber 311, the gate valve 120b is installed which isolates both chambers from each other and can open/close at need.

In the sputtering apparatus chamber 511, targets 514a, 514b, and 514c of Ru, CoFe (Co:Fe=90:10), and Al are positioned at the ceiling part thereof via the respective target cathodes (not shown) relative to the substrate 513 placed on the substrate holder 512 at the bottom center of the chamber, respectively. As illustrated in FIG. 11, the sputtering apparatus chamber 511 also allows mounting a target 514d, and the target 514d can be appropriately used depending on the use mode. Between the core chamber 116 and the sputtering apparatus chamber 511, the gate valve 120c is installed which isolates both chambers from each other and can open/close at need.

In the sputtering apparatus chamber 711, targets 714a, 714b, and 714c of CoFe (Co:Fe=90:10), NiFe (Ni:Fe=80:20), and Ta are positioned via the respective target cathodes (not shown) relative to a substrate 713 placed on a substrate 713 on a substrate holder 712 at the bottom center of the chamber, respectively. As illustrated in FIG. 11, the sputtering apparatus chamber 711 also allows mounting targets 714d and 714e, and the targets 714d and 714e can be appropriately used depending on the use mode. Between the core chamber 116 and the sputtering apparatus chamber 711, the gate valve 120e is installed which isolates both chambers from each other and can open/close at need.

In the sputtering apparatus chambers 311, 511 and 711, the gas used for sputtering adopts sole Ar. The substrate has a diameter of 200 mm, and the target has a diameter of 164 mm. As in the case of Example 2, there are requirements on practical application, specifically in the case of using many target cathodes, to avoid influence between cathodes and to avoid unnecessary floor space for installing the apparatus. Accordingly, the angle θ between the substrate and the target is determined for each chamber responding to the above requirements. As described in Example 1, the film-thickness distribution deteriorates at excessively large θ or at excessively small θ, thus a practically preferred angle is in a range of [5°≦θ45°]. Example 2 adopts 15° or 30° depending on the chamber.

For the case of specifically many kinds of films are deposited as in Example 2, the film-thickness distribution differs to some extent depending on the target material, thus the value of T/W is determined for each chamber aiming at the optimum distribution margin. As described in Example 1, the film-thickness distribution mostly depends on the ratio of the distance T to the distance W, giving practically good film-thickness distributions in an approximate range of [0.7≦T/W≦1.6]. Example 2 adopts conditions of T/W=0.8, 1.1 or 1.3. With similar reason, it is preferable that the distance T between the center of the target or the target cathode and a plane including the surface of the substrate or the substrate holder is in a range of [50 mm≦T≦800 mm]. Example 2 adopts the distance T of 200, 250 or 300 mm. As illustrated in FIG. 1, the T is defined as the vertical distance between the target center A and the substrate center O, and the W is defined as the horizontal distance between the target center A and the substrate center O.

The cleaning chamber 211 of the magnetic multilayer film-manufacturing apparatus 1100 shown in FIG. 11 has an ion-beam etching means and an RF-sputtering etching means relative to the substrate 213 placed on the substrate holder 212 at the bottom center of the chamber, thereby conducting the cleaning of substrate by the physical etching before depositing the film. Between the core chamber 116 and the cleaning chamber 211, there is installed the gate valve 120a which isolates both chambers from each other and can open/close at need.

The oxidation treatment chamber 611 of the magnetic multilayer film-manufacturing apparatus 1100 shown in FIG. 11 has an oxygen-introducing means for conducting surface chemical reaction to oxidize the metal layer relative to the substrate 612 placed on the substrate holder 613 at the bottom center of the chamber. Example 2 adopts natural oxidation in an oxygen atmosphere under reduced pressure. Between the core chamber 116 and the oxidation treatment chamber 611, there is installed the gate valve 120d which isolates both chambers from each other and can open/close at need.

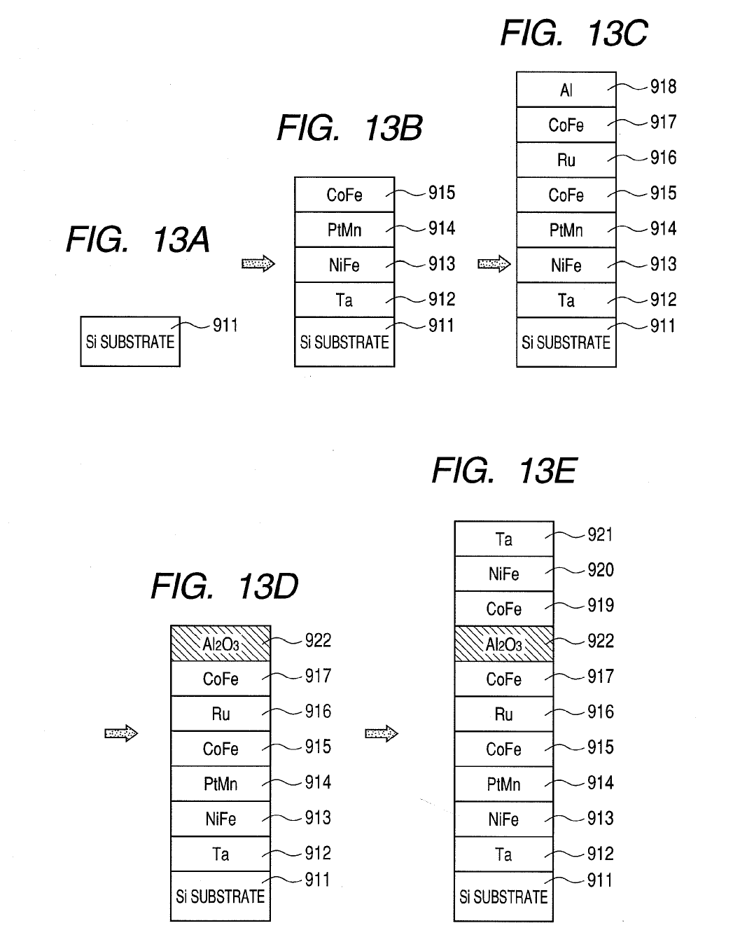

The procedure for forming MTJ having the structure given in FIG. 12 in the apparatus 1100 of FIG. 11 will be described below referring to FIGS. 12 and 13. FIG. 13 illustrates the process to form the MTJ having the structure of FIG. 12. The MTJ given in FIG. 12 has a structure of Si-substrate 911 with laminations of layers of, in the order of, Ta 912, NiFe 913, PtMn 914, CoFe 915, Ru 916, CoFe 917, Al₂O₃ 922, CoFe 919, NiFe 920, and Ta 921.

(1) First, the Si-substrate 911 given in FIG. 13A is placed in the load-lock chamber 113 of the multi-chamber apparatus 1100 provided with the present invention given in FIG. 11. (2) The load-lock chamber 113 is evacuated. (3) The vacuum transfer robot 117 transfers the Si-substrate 911 from the load-lock chamber 113 to the cleaning chamber 211, where the ion-beam etching mechanism and the RF-sputtering etching mechanism etch the surface of the substrate, thus executing surface cleaning and flattening. (4) The Si-substrate 911 is transferred to the sputtering apparatus chamber 311 provided with the present invention, where the film-deposition is executed on the Si-substrate 911 in a sequence of 5 nm of Ta film 912, 1 nm of NiFe film 913, 15 nm of PtMn film 914, and 2.5 nm of CoFe film 915. Thus deposited film structure is shown in FIG. 13B.

The substrate after depositing films as shown in FIG. 13B is then transferred to the sputtering apparatus chamber 511 of the present invention, where the films of 0.8 nm of Ru film 916, and 3 nm of CoFe film 917 are deposited on the CoFe film 915. Then, Al film 918 of 0.8 nm is further deposited on the substrate under the conditions of 0.019 Pa of pressure, 30 sccm of argon (Ar) gas flow rate, 300 W of DC power, and 17.5 sec of film-deposition time. The structure of thus formed films is shown in FIG. 13C.

The substrate with the deposited films as shown in FIG. 13C is then transferred to the oxidation treatment chamber 611, where the oxidation is executed under an oxygen atmosphere, 1000 Pa of chamber pressure, for 10 minutes of oxidation time, thus oxidizing the Al film 918 to form aluminum oxide (Al₂O₃) 922. Thus formed structure is shown in FIG. 13D.

The substrate with the deposited films as shown in FIG. 13D is then transferred to the sputtering apparatus chamber 711 provided with the present invention, where 2 nm of CoFe film 919, 1 nm of NiFe film 920, and 10 nm of Ta film 921 are deposited on the aluminum oxide (Al₂O₃) 922. Thus formed structure is shown in FIG. 13E.

The substrate with the deposited films as shown in FIG. 13E is then transferred to the load-lock chamber 114 by the vacuum transfer robots 117 and 118. From the load-lock chamber 114, the substrate is transferred to a substrate cassette (not shown) by a pneumatic conveying system (not shown). Through the procedure, the MTJ having the structure of FIG. 12 can be formed.

Following is the description of the method for evaluating the electric characteristics of MTJ structure formed by the above-procedure of film-deposition in the multi-chamber apparatus provided with the method and apparatus of the present invention. The MTJ obtained using the apparatus of FIG. 11 and the procedure of FIG. 13 was investigated at 49 positions distributed over the whole surface of circular area of 188 mm in diameter relative to the 200 mm diameter substrate, using a 12-terminals probe Current-In-Plane-Tunneling (CIPT) method. The measurement principle of the CIPT method is described in D. C. Worledge and P. L. Trouilloud, “Applied Physics Letters”, 83, pp. 84-86, (2003).

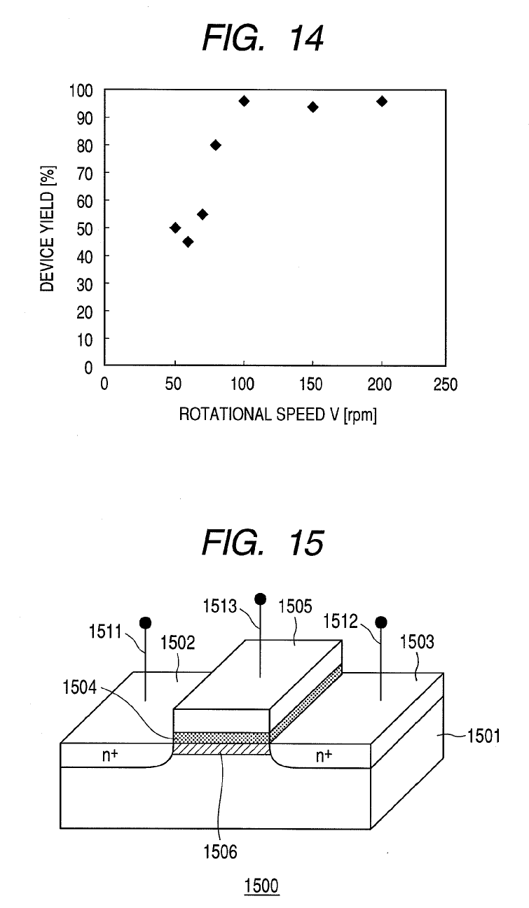

Next, the description is given to the observed electric characteristics of the MTJ structure obtained from the procedure of FIG. 13 for the case of varying the substrate rotational speed in a range from 50 to 200 rpm, or varying the total number of rotations in a range from 14.58 to 58.33. FIG. 14 is a graph with the horizontal axis of the substrate rotational speed (rpm), and the vertical axis of the device production yield (%). The target performance is RA value 100Ω·μm²±10% in a zone of 188 mm of surface diameter relative to 200 mm diameter of substrate. It was found that exceeding the 60 rpm (total number of rotations of 17.5) increases the quantity of devices satisfying the target performance, or increases the device production yield.

The structure of MTJ used for the MRAM device formed in Example 2 is illustrated in FIG. 12. Among the variables affecting the device characteristics for MRAM device, the film thickness and the film quality of the tunnel insulation film 922 are the specifically largely-affecting variables. Many of the tunnel insulation films have about 1 nm in thickness, which is the thinnest level in the MTJ structure, and the tunnel insulation film significantly affects the important characteristics of NTJ structure, both the interconnection resistance (RA) and the ratio of resistivity (MR ratio) between the case of the same directions of spin in pin-layer and free-layer sandwiching the tunnel insulation film and the case of different directions thereof. In Example 2, the Al₂O₃ film 922 of FIG. 12 is the tunnel insulation film, having a thickness of 0.8 nm. The performance of device is significantly affected by the interconnection resistance (RA) and the ratio of resistivity (MR ratio) between the case of the same directions of spin in pin-layer and free-layer sandwiching the tunnel insulation film and the case of different directions thereof. Even when the case of different MTJ structure, the film thickness and the film quality of the tunnel insulation film are important in principle, and similarly the uniformity of thickness and the uniformity of quality of the tunnel insulation film are important to the device production yield.

The structure of MTJ film given in FIG. 12 is a multilayer film giving less than 50 nm in total thickness. The thickness of films in the MTJ structuring films other than the tunnel insulation film is very thin, ranging from less than 1 nm to about 15 nm. Specifically the magnetic films of CoFe and NiFe have about 1 nm at the thinnest one. Therefore, uniform deposition of each film other than the tunnel insulation film is also important for the device production yield.

In Example 2, the multilayer film is structured by very thin films so that the film-thickness distribution in every film for actual device structure was not able to be determined, though it was determined in Example 1. Considering, however, that Example 2 confirmed a drastic improvement in the device characteristics by bringing the substrate rotational speed to 60 rpm or more, the improvement in the device characteristics presumably came from the total improvement in the uniformity of film thickness and film quality on each film of the thin multilayer, including the tunnel insulation film, similar to the case of Example 1.

Although Example 2 uses a 200 mm substrate, larger ones such as 300 mm or larger diameter may be adopted. Alternatively, smaller substrate such as 150 mm or smaller diameter may be used. The same performance can be attained in the case that the diameter of substrate holder and of substrate-placing table is not changed, that the pluralities of small substrates are placed on the substrate-placing table of the substrate holder, and that the substrate is rotated together with the substrate holder or the substrate is rotated. In this case, the pluralities of small substrates may be placed on the respective trays or the like, which are then placed on the substrate-placing table. Example 2 adopts one target to one film. To increase the film-deposition speed, however, pluralities of targets of the same kind may be arranged to each of the pluralities of target cathodes, thus using them at a time. Alternatively, to extend the exchange cycle of the target, pluralities of targets may be arranged to each of the pluralities of target cathodes, thus using them at a time or using them separately. Furthermore, to improve the desired film characteristics, pluralities of targets of different kinds may be discharged at a time.

Although Example 2 adopts the MTJ structure given in FIG. 12, other structures may be applied. Example 2 uses alumina (Al₂O₃) for the tunnel insulation film. However, insulation films made of other materials such as magnesium oxide (MgO) may be used. For forming the insulation film, Example 2 adopts the two-stage method giving oxidation after metal-film deposition. However, there can be adopted other methods such as the one applying RF to the target using the material of the insulation film, and the one depositing the insulation film directly by reactive-sputtering using a metal target and an inert gas (Ar or the like) containing oxygen. As of the two-stage method for forming the tunnel insulation film, Example 2 uses the natural oxidation method in an oxygen atmosphere to oxidize the metal. There is also applicable other method such as thermal oxidation by heating the substrate, plasma oxidation using the oxygen active species generated from plasma, and oxidation through transferring oxygen active species.

The cleaning of substrate surface is conducted by the ion-beam etching mechanism and the RF-sputtering etching mechanism. One of these mechanisms may be applied separately, and other methods such as etching accompanied with chemical action may be used if only the desired object is attained.

1.-54. (canceled)

55. A sputtering method for forming a gate insulation film having 1 nm or smaller thickness of MOSFET comprising the steps of:
placing a target material of at least one metal selected from the metal group consisting of hafnium, zirconium, lanthanum, titanium, and tantalum; an alloy thereof; or an oxide, a nitride, or an oxide thereof, on a sputtering cathode installed in a sputtering apparatus chamber;
placing a substrate on a substrate holder rotatably installed in the sputtering apparatus chamber;
sputtering a target material on the surface of the substrate with the surface of the placed substrate and the surface of the placed target material being non-parallel with each other, so that the target material comes flying at a slant on the surface of the substrate to form a film; and
treating the formed film on the surface of the substrate to form the gate insulation film, the diameter D of the target material being smaller than the diameter d of the substrate, wherein
during the film-forming step by sputtering, the substrate holder mounting the substrate thereon is rotated at 100 rpm or larger rotational speed, and a condition of 0.8≦T/W≦1.3 is set, where T is the distance between the center of the sputtering cathode and a plane including the surface of the substrate-placing table, and W is the distance on a line, passing through the center of the sputtering cathode and being in parallel to the surface of the substrate-holding table, between the center of the sputtering cathode and the point of intersection of the line with a normal b passing through the center of the substrate-placing table.

56. A sputtering method according to claim 55, wherein the distance T is set to be 50 mm≦T≦800 mm.

57. A sputtering method for forming a tunnel insulation film having 1 nm or smaller thickness of magnetoresistive element comprising the steps of:
placing a target material of at least one metal selected from the metal group consisting of aluminum, magnesium, alumina and magnesium oxide, on a sputtering cathode installed in a sputtering apparatus chamber;
placing a substrate on a substrate holder rotatably installed in the sputtering apparatus chamber;
sputtering a target material on the surface of the substrate with the surface of the placed substrate and the surface of the placed target material being non-parallel with each other, so that the target material comes flying at a slant on the surface of the substrate to form a film; and
treating the formed film on the surface of the substrate to form the tunnel insulation film, the diameter D of the target material being smaller than the diameter d of the substrate, wherein
during the film-forming step by sputtering, the substrate holder mounting the substrate thereon is rotated at 100 rpm or larger rotational speed, and a condition of 0.8≦T/W≦1.3 is set, where T is the distance between the center of the sputtering cathode and a plane including the surface of the substrate-placing table, and W is the distance on a line, passing through the center of the sputtering cathode and being in parallel to the surface of the substrate-holding table, between the center of the sputtering cathode and the point of intersection of the line with a normal b passing through the center of the substrate-placing table.

58. A sputtering method according to claim 57, wherein the distance T is set to be 50 mm≦T≦800 mm.
